(19) United States
(12) Patent Application Publication
(10) Pub. No.: US 2015/0228457 A1
(43) Pub. Date: Aug. 13, 2015

(54) GAS SUPPLY METHOD AND PLASMA PROCESSING APPARATUS

(71) Applicant: TOKYO ELECTRON LIMITED, Tokyo (JP)

(72) Inventors: Kazuo Yamashita, Miyagi (JP); Yuichirou Sekimoto, Miyagi (JP); Atsushi Sawachi, Miyagi (JP)

(73) Assignee: TOKYO ELECTRON LIMITED, Tokyo (JP)

(21) Appl. No.: 14/422,329

(22) PCT Filed: Sep. 10, 2013
(86) PCT No.: PCT/JP2013/074375

§ 371 Date: Feb. 18, 2015

Related U.S. Application Data
(60) Provisional application No. 61/705,688, filed on Sep. 26, 2012.

(30) Foreign Application Priority Data
Sep. 21, 2012 (JP) 2012-208730

(51) Int. Cl. H01J 37/32; C23C 16/455; H01L 21/67; C23C 16/52

(52) U.S. Cl. CPC H01J 37/3244; C23C 16/52; C23C 16/455; H01J 37/32449; H01L 21/67069; H01J 2237/334; H01J 2237/332

(57) ABSTRACT

In the present invention, a gas supply method includes a selecting step and an additive gas supply step. The selecting step involves selecting, in accordance with the type of target film to be processed, a combination of a gas chamber into which additive gas is supplied and the type of additive gas, the gas chamber being selected from a plurality of gas chambers which are divided from a gas injection unit for injecting plasma processing gases into a processing chamber in which a substrate formed with a processing target film is placed. In the additive gas supply step, the additive gas is supplied to the gas chamber on the basis of the combination selected in the selecting step.

### TECHNICAL FIELD

Various aspects and exemplary embodiments of the present disclosure relate to a gas supply method and a plasma processing apparatus.

### BACKGROUND

A plasma processing apparatus is widely used in a semiconductor fabrication process to execute a plasma processing for the purpose of thin film deposition or etching, for example. The plasma processing apparatus may be exemplified by a plasma chemical vapor deposition (CVD) apparatus that performs deposition of a thin film, or a plasma etching apparatus that performs etching.

The plasma processing apparatus includes, for example, a processing chamber in which a substrate having a processing target film formed thereon is placed as an object for plasma processing, a shower head serving as a gas injection unit to inject a processing gas required for plasma processing into the processing chamber, and a sample stand configured to install the substrate in the processing chamber. In addition, the plasma processing apparatus may include, for example, a plasma generation mechanism configured to supply electric energy such as, for example, microwaves or high frequency waves, so as to turn the processing gas within the processing chamber into plasma.

In a plasma processing apparatus, a technology is known in which a density of gas is locally adjusted within a processing chamber so as to maintain uniformity of a processing target surface of a processing target film which is an object for plasma processing. For example, Patent Document 1 discloses a technology in which the interior of a shower head configured to inject a processing gas into a processing chamber is divided into a plurality of gas chambers so as to supply any types of or any flow rates of processing gas to a gas chamber corresponding to a central portion of a substrate and a gas chamber corresponding to a peripheral portion of the substrate, respectively. In addition, for example, Patent Document 2 discloses a technology in which an additive gas to be added to a processing gas is supplied as needed.

### PRIOR ART DOCUMENT

### Patent Document

Patent Document 1: Japanese Patent Laid-Open Publication No. 2012-114275

Patent Document 2: Japanese Patent Laid-Open Publication No. 2007-214295

### SUMMARY OF THE INVENTION

### Problems to be Solved

However, the related art has a problem in that the uniformity of the processing target surface of the processing target film which is an object for plasma processing may not be maintained following the change of processing target films. That is, in the related art, once the type or flow rate of gas supplied to each gas chamber was selected, the selected type of gas is continuously supplied at the selected flow rate even when processing target films are changed. Therefore, uniformity may not be maintained on a processing target surface of a processing target film after the processing target films are changed.

### Means to Solve the Problems

A gas supply method according to an aspect of the present disclosure includes: a selection step of selecting a combination of a gas chamber to be supplied with an additive gas among a plurality of gas chambers obtained by partitioning a gas injection unit and a type of additive gas according to a type of processing target film; and an additive gas supply step of supplying the additive gas into the gas chamber based on the combination selected by the selection step. The gas injection unit is configured to inject a processing gas for use in a plasma processing into a processing chamber in which a substrate formed with the processing target film is placed.

### Effect of the Invention

According to various aspects and exemplary embodiments of the present disclosure, there are provided a gas supply method and a plasma processing apparatus, which are capable of appropriately maintaining uniformity of a processing target surface of a processing target film following the change of processing target films to be treated by plasma processing.

### BRIEF DESCRIPTION OF THE DRAWINGS

FIG. 1 is a cross-sectional view illustrating a schematic configuration of a plasma processing apparatus according to an exemplary embodiment.

FIG. 2 is a horizontal cross-sectional view illustrating an inner upper electrode in the present exemplary embodiment.

FIG. 3 is a block diagram illustrating an exemplary configuration of a control unit in the present exemplary embodiment.

FIG. 4 is a view illustrating an exemplary structure of data stored in a memory unit in the present exemplary embodiment.

FIG. 5 is a flowchart illustrating a processing sequence of a gas supply method by a plasma processing apparatus according to the present exemplary embodiment.

FIG. 6A is a view illustrating an etch rate when a wafer was etched without using the gas supply method of the present exemplary embodiment.

FIG. 6B is a view illustrating an etch rate when a wafer was etched using the gas supply method of the present exemplary embodiment.

FIG. 6C is a view illustrating an etch rate when a wafer was etched without using the gas supply method of the present exemplary embodiment.

FIG. 7A is a view illustrating an etch rate when a wafer was etched without using the gas supply method of the present exemplary embodiment.

FIG. 7B is a view illustrating an etch rate when a wafer was etched using the gas supply method of the present exemplary embodiment.

FIG. 8A is a view illustrating an etch rate when a wafer was etched without using the gas supply method of the present exemplary embodiment.

FIG. 8B is a view illustrating an etch rate when a wafer was etched using the gas supply method of the present exemplary embodiment.

FIG. 8C is a view illustrating an etch rate when a wafer was etched using the gas supply method of the present exemplary embodiment.

FIG. 9A is a view illustrating an etch rate when a wafer was etched without using the gas supply method of the present exemplary embodiment.

FIG. 9B is a view illustrating an etch rate when a wafer was etched using the gas supply method of the present exemplary embodiment.

FIG. 9C is a view illustrating an etch rate when a wafer was etched using the gas supply method of the present exemplary embodiment.

FIG. 10A is a view illustrating an etch rate when a wafer was etched without using the gas supply method of the present exemplary embodiment.

FIG. 10B is a view illustrating an etch rate when a wafer was etched using the gas supply method of the present exemplary embodiment.

FIG. 10C is a view illustrating an etch rate when a wafer was etched using the gas supply method of the present exemplary embodiment

### DETAILED DESCRIPTION TO EXECUTE THE INVENTION

Hereinafter, various exemplary embodiments will be described in detail with reference to the accompanying drawings. In addition, the same or corresponding parts of the respective drawings are designated by the same reference numerals.

A gas supply method includes: a selection step of selecting a combination of a gas chamber to be supplied with an additive gas among a plurality of gas chambers obtained by partitioning a gas injection unit and a type of additive gas according to a type of processing target film; and an additive gas supply step of supplying the additive gas into the gas chamber based on the combination selected by the selection step. The gas injection unit is configured to inject a processing gas for use in a plasma processing into a processing chamber in which a substrate formed with the processing target film is placed.

In an exemplary embodiment of the gas supply method, the selection step selects the combination of supplying a first etching gas as the additive gas to the gas chamber located at a position corresponding to a central portion of the substrate, among the gas chambers when the type of processing target film is an organic film.

In an exemplary embodiment of the gas supply method, the selection step selects the combination of supplying a first deposition gas as the additive gas to the gas chamber located at a position outside of a peripheral portion of the substrate, among the gas chambers when the type of processing target film is an organic film.

In an exemplary embodiment of the gas supply method, the selection step selects the combination of supplying a second etching gas as the additive gas to the gas chamber located at a position corresponding to a central portion of the substrate, among the gas chambers when the type of processing target film is a silicon film.

In an exemplary embodiment of the gas supply method, the selection step selects the combination of supplying a second deposition gas as the additive gas to the gas chamber located at a position outside of a peripheral portion of the substrate, among the gas chambers when the type of processing target film is a silicon film.

In an exemplary embodiment of the gas supply method, the first etching gas is O₂ gas.

In an exemplary embodiment of the gas supply method, the first deposition gas is at least one of a CF-based gas and COS gas.

In an exemplary embodiment of the gas supply method, the second etching gas is at least one of HBr gas, NF₃ gas, and Cl₂ gas.

In an exemplary embodiment of the gas supply method, the second deposition gas is O₂ gas.

In an aspect of the present disclosure, a plasma processing apparatus includes: a processing chamber in which a substrate formed with a processing target film is placed; a gas injection unit configured to inject a processing gas for use in plasma processing into the processing chamber; an additive gas supply unit configured to supply an additive gas to a plurality of gas chambers obtained by partitioning the gas injection unit; and a control unit configured to select a combination of a gas chamber to be supplied with the additive gas among the gas chambers and a type of additive gas according to a type of processing target film, and to supply the additive gas from the additive gas supply unit to the gas chamber based on the selected combination.

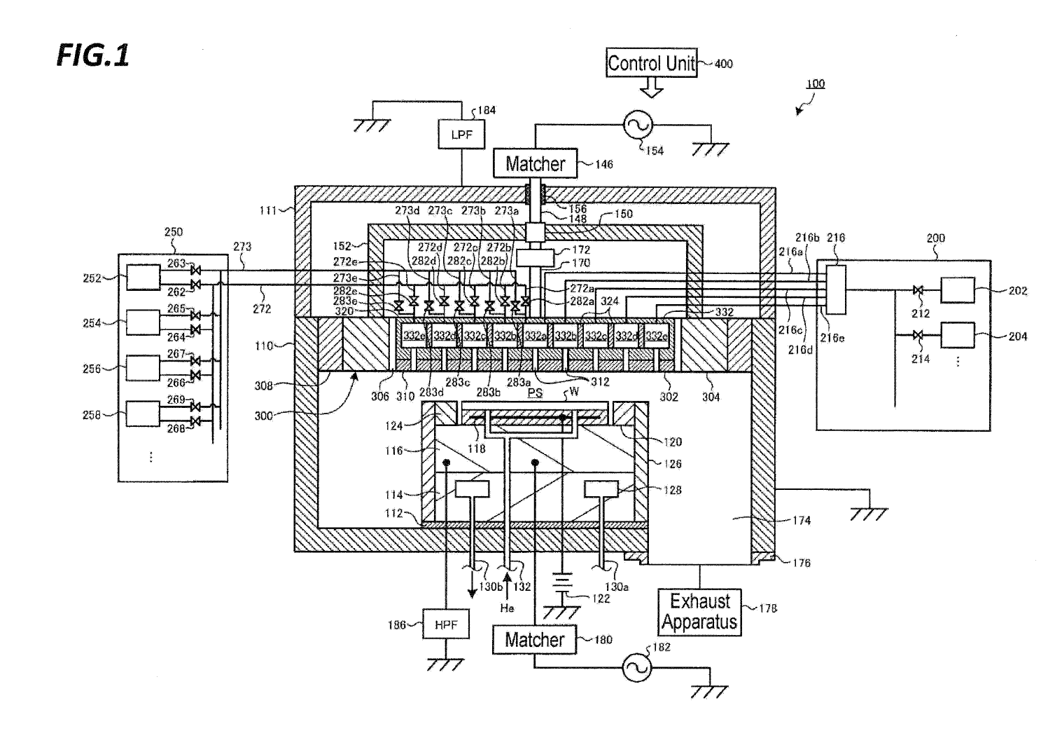

FIG. 1 is a cross-sectional view illustrating a schematic configuration of a plasma processing apparatus according to an exemplary embodiment. Here, descriptions will be made on an example in which the plasma processing apparatus according to the present exemplary embodiment is applied to a parallel flat-plate type plasma etching device.

The plasma processing apparatus 100 includes a processing chamber 110 configured by a substantially cylindrical processing container. The processing container is formed of, for example, an aluminum alloy, and electrically grounded. In addition, an inner wall surface of the processing container is coated with an alumina film or an yttrium oxide film (Y₂O₃).

A susceptor 116 is placed in the processing chamber 110, in which the susceptor 16 constitutes a lower electrode that also serves as a stand on which a wafer W as a substrate is disposed. Specifically, the susceptor 116 is supported by a cylindrical susceptor support member 114 provided approximately at the center of an inner bottom surface of the processing chamber 110 with an insulation plate 112 interposed therebetween. The susceptor 116 is formed of, for example, an aluminum alloy.

An electrostatic chuck 118 is provided on the top of the susceptor 116 to hold a wafer W. The electrostatic chuck 118 includes an electrode 120 therein. A direct current (DC) power source 122 is electrically connected to the electrode 120. The electrostatic chuck 118 allows the wafer W to be attracted to the top surface thereof by Coulomb force generated when DC voltage is applied to the electrode 120 from the DC power source 122.

In addition, a focus ring 124 is disposed on the top surface of the susceptor 116 to surround the periphery of the electrostatic chuck 118. In addition, a cylindrical inner wall member 126 formed of, for example, quartz is attached to outer circumferential surfaces of the susceptor 116 and the susceptor support member 114.

A ring-shaped coolant chamber 128 is formed within the susceptor support member 114. The coolant chamber 128 is in communication with, for example, a chiller unit (not illustrated) installed outside of the processing chamber 110, through pipes 130a and 130b. A coolant (coolant solution or cooling water) is circulated through the pipes 130a and 130b and supplied to the coolant chamber 128. In this way, the temperature of the wafer W on the susceptor 116 may be controlled.

A gas supply line 132 penetrates the interior of the susceptor 116 and the susceptor support member 114 to the top surface of the electrostatic chuck 118. A heat transfer gas (backside gas) such as, for example, He gas, may be supplied to a gap between the wafer W and the electrostatic chuck 118 through the gas supply line 132.

An upper electrode 300 is provided above the susceptor 116 to face, in parallel, the susceptor 116 that constitutes the lower electrode. A plasma generation space PS is formed between the susceptor 116 and the upper electrode 300.

The upper electrode 300 includes a disc-shaped inner upper electrode 302 and a ring-shaped outer upper electrode 304 surrounding the outer periphery of the inner upper electrode 302. The inner upper electrode 302 configures a shower head to eject a prescribed gas including a processing gas to the plasma generation space PS above the wafer W disposed on the susceptor 116. The inner upper electrode 302 is an example of a gas injection unit that supplies a processing gas for use in plasma processing into the processing chamber 110 in which a substrate formed with a processing target film is placed.

The inner upper electrode 302 includes a circular electrode plate 310 having a plurality of gas ejection holes 312 and an electrode support body 320 configured to removably support the top surface of the electrode plate 310. The electrode support body 320 takes a form of a disc having substantially the same diameter as the electrode plate 310. A detailed exemplary configuration of the inner upper electrode 302 will be described later.

A ring-shaped dielectric material 306 is interposed between the inner upper electrode 302 and the outer upper electrode 304. A ring-shaped insulative shield member 308 is hermetically interposed between the outer upper electrode 304 and the inner circumferential wall of the processing chamber 110 and is formed of alumina, for example.

A first high frequency power source 154 is electrically connected to the outer upper electrode 304 through a power feeing cylinder 152, a connector 150, an upper power feeding rod 148, and a matcher 146. The first high frequency power source 154 may output high frequency power having a frequency of 40 MHz or more (e.g., 100 MHz).

The power feeding cylinder 152 is formed, for example, substantially in a bottom-opened cylindrical shape and the lower end of the power feeding cylinder 152 is connected to the outer upper electrode 304. The lower end of the upper power feeding rod 148 is electrically connected to a central portion of the upper surface of the power feeding cylinder 152 via the connector 150. The upper end of the upper power feeding rod 148 is connected to an output side of the matcher 146. The matcher 146 may be connected to the first High frequency power source 154 so as to match an inner impedance of the first high frequency power source 154 with a load impedance.

The exterior of the power feeding cylinder 152 is covered with a cylindrical ground conductor 111, of which the side wall has substantially the same diameter as the processing chamber 110. The lower end of the ground conductor 111 is connected to the top of a side wall of the processing chamber 110. The upper power feeding rod 148 as described above penetrates the central portion of the top surface of the ground conductor 111, and an insulation member 156 is interposed between a contact portion of the ground conductor 111 and the upper power feeding rod 148.

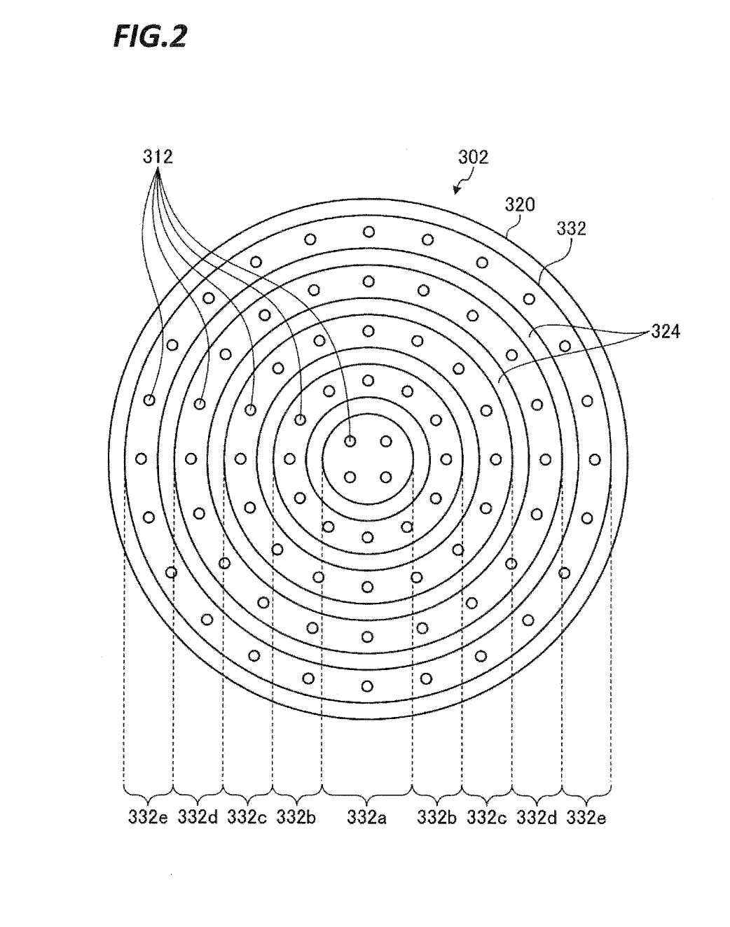

Now, a detailed exemplary configuration of the inner upper electrode 302 will be described in detail with reference to FIGS. 1 and 2. FIG. 2 is a horizontal cross-sectional view of the inner upper electrode in the present exemplary embodiment.

As illustrated in FIG. 2, a buffer chamber 332 formed in a disc shape is provided in the inner upper electrode 302. The inner upper electrode 302 has a plurality of gas chambers 332a to 332e divided from the buffer chamber 332 by partitions 324. The gas chambers 332a to 332e are provided with the gas injection holes 312, through which a processing gas is ejected into the processing chamber 110.

The gas chamber 332a is a gas chamber located at a position corresponding to the central portion of the wafer W. The gas chamber 332b is a gas chamber located at a position corresponding to the central portion of the wafer W and surrounds the periphery of the gas chamber 332a. In the following description, the gas chamber 332a will be referred to as a “central gas chamber 332a” and the gas chamber 332b will be referred to as a “central gas chamber 332b”.

The gas chamber 332c is a gas chamber located at a position corresponding to the peripheral portion of the wafer W and surrounds the periphery of the central gas chamber 332b. In the following description, the gas chamber 332c will be properly referred to as a “peripheral gas chamber 332c”.

The gas chamber 332d is a gas chamber located at a position corresponding to the position of the focus ring 124 which is located outside of the peripheral portion of the wafer W. The gas chamber 332e is a gas chamber located at a position corresponding to a position outside of the focus ring 124 and surrounds the periphery of the gas chamber 332d. In the following description, the gas chamber 332d will be referred to as an “outer gas chamber 332d” and the gas chamber 332e will be referred to as an “outer gas chamber 332e”.

A processing gas for use in plasma processing is supplied to the gas chambers 332a to 332e from a processing gas supply unit 200 (described below). The processing gas, supplied to the central gas chambers 332a and 332b, is ejected from the gas injection holes 312 to the central portion of the wafer W. The processing gas supplied to the peripheral gas chamber 332c is ejected from the gas injection holes 312 to the peripheral portion of the wafer W. The processing gas supplied to the outer gas chambers 332d and 332e is ejected from the gas injection holes 312 to a position outside of the peripheral portion of the wafer W.

In addition, an additive gas to be added to the processing gas is optionally supplied to the gas chambers 332a to 332e from an additive gas supply unit 250 (described below). The additive gas, supplied to the central gas chambers 332a and 332b, is ejected, along with the processing gas, from the gas injection holes 312 to the central portion of the wafer W. The additive gas, supplied to the peripheral gas chamber 332c, is ejected, along with the processing gas, from the gas injection holes 312 to the peripheral portion of the wafer W. The additive gas, supplied to the outer gas chambers 332d and 332e, is ejected, along with the processing gas, from the gas injection holes 312 to the positions outside the peripheral portion of the wafer W.

Referring back to FIG. 1, a lower power feeding rod 170 is electrically connected to the top surface of the electrode support body 320. The lower power feeding rod 170 is connected to the upper power feeding rod 148 via the connector 150. A variable condenser 172 is provided in the middle of the lower power feeding rod 170. By adjusting the electrostatic capacitance of the variable condenser 172, it may be able to adjust a relative ratio between the intensity of an electric field generated immediately below the outer upper electrode 304 and the intensity of an electric field generated immediately below the inner upper electrode 302 when high frequency power is applied from the first high frequency power source 154.

An exhaust port 174 is formed in the bottom of the processing chamber 110. The exhaust port 174 is connected to an exhaust apparatus 178 including, for example, a vacuum pump, through an exhaust pipe 176. As the exhaust apparatus 178 evacuates the processing chamber 110, the interior of the processing chamber 110 may be decompressed to a desired pressure.

A second high frequency power source 182 is electrically connected to the susceptor 116 through a matcher 180. The second high frequency power source 182 may output high frequency power having a frequency within a range of 2 MHz to 20 MHz, for example, 13 MHz.

A low-pass filter 184 is electrically connected to the inner upper electrode 302 of the upper electrode 300. The low-pass filter 184 serves to shut off high frequency power from the first high frequency power source 154, and to allow high frequency power from the second high frequency power source 182 to pass through a ground. Meanwhile, the susceptor 116 constituting the lower electrode is electrically connected to a high-pass filter 186. The high-pass filter 186 serves to allow high frequency power from the first high frequency power source 154 to pass through the ground.

The processing gas supply unit 200 includes a gas source 202 and a gas source 204. The gas source 202 and the gas source 204 supply processing gases for use in a plasma process such as, for example, plasma etching or a plasma CVD process, into the gas chambers 332a to 332e of the inner upper electrode 302. For example, the gas source 202 supplies CF₄ gas/CHF₃ gas as a processing gas into the gas chambers 332a to 332e of the inner upper electrode 302 when plasma etching process of an organic film such as, for example, a bottom anti-reflective coating (BARC) is performed. In addition, the gas source 204 supplies HBr gas/He gas/O₂ gas as a processing gas into the gas chambers 332a to 332e of the inner upper electrode 302 when plasma etching process of a silicon film is performed. In addition, although not illustrated, the processing gas supply unit 200 supplies a gas (e.g., He gas) for use in various processes of the plasma processing apparatus 100.

In addition, the processing gas supply unit 200 includes flow rate adjustment valves 212 and 214 provided between the respective gas sources 202 and 204 and the gas chambers 332a to 332e of the inner upper electrode 302 and a flow splitter 216 connected to the flow rate adjustment valves 212 and 214. The flow splitter 216 is connected to branch flow paths 216a to 216e, and the branch flow paths 216a to 216e are respectively connected to the gas chambers 332a to 332e of the inner upper electrode 302. The flow rates of the processing gases supplied into the gas chambers 332a to 332e of the inner upper electrode 302 are controlled by the flow rate adjustment valves 212 and 214.

The additive gas supply unit 250 includes a gas source 252, a gas source 254, a gas source 256, and a gas source 258. The gas source 252, gas source 254, gas source 256, and gas source 258 selectively supply any of additive gases, which will be added to the processing gases, into any gas chamber from the gas chambers 332a to 332e of the inner upper electrode 302. For example, the gas source 252 supplies a first etching gas as an additive gas into the central gas chamber 332a and/or the central gas chamber 332b among the gas chambers 332a to 332e of the inner upper electrode 302 when plasma etching is performed on an organic film such as, for example, a BARC. The first etching gas is a gas to facilitate the progress of plasma etching, for example, O₂ gas. In addition, the gas source 254 supplies a first deposition gas as an additive gas to the outer gas chamber 332d and/or the outer gas chamber 332e among the gas chambers 332a to 332e of the inner upper electrode 302 when plasma etching is performed on an organic film such as, for example, a BARC. The first deposition gas is a gas to delay the progress of plasma etching. For example, the first deposition gas is at least one of a CF-based gas, such as, for example, CH₂F₂ gas, and COS gas. In addition, the gas source 256 supplies a second etching gas as an additive gas to the central gas chamber 332a and/or the central gas chamber 332b among the gas chambers 332a to 332e of the inner upper electrode 302 when plasma etching is performed on a silicon film. The second etching gas is a gas to facilitate the progress of plasma etching. For example, the second etching gas is at least one of HBr gas, NF₃ gas and Cl₂ gas. In addition, the gas source 258 supplies a second deposition gas as an additive gas into the outer gas chamber 332d and/or the outer gas chamber 332e among the gas chambers 332a to 332e of the inner upper electrode 302 when plasma etching is performed on a silicon film. The second deposition gas is a gas to delay the progress of plasma etching, for example, O₂ gas.

In addition, the additive gas supply unit 250 includes flow rate adjustment valves 262, 264, 266 and 268 and flow rate adjustment valves 263, 265, 267 and 269 provided between the respective gas sources 252, 254, 256 and 258 and the gas chambers 332a to 332e of the inner upper electrode 302.

The flow rate adjustment valves 262, 264, 266 and 268 are connected to a confluence flow path 272 that merges outputs of the respective flow rate adjustment valves 262, 264, 266 and 268 and, in turn, the confluence flow path 272 is diverged into branch flow paths 272a to 272e. The branch flow paths 272a to 272e are respectively connected to the gas chambers 332a to 332e of the inner upper electrode 302. The branch flow paths 272a to 272e are provided with opening/closing valves 282a to 282e, respectively. The opening/closing valves 282a to 282e serve to perform switching between supply of additive gases from the respective gas sources 252, 254, 256 and 258 and supply stop. The flow rates of additive gases to be supplied into the gas chambers 332a to 332e of the inner upper electrode 302 are controlled by, for example, the flow rate adjustment valves 262, 264, 266 and 268.

The flow rate adjustment valves 263, 265, 267 and 269 are connected to a confluence flow path 273 that merges outputs of the respective flow rate adjustment valves 263, 265, 267 and 269 and the confluence flow path 273 is diverged into branch flow paths 273a to 273e. The branch flow paths 273a to 273e are respectively connected to the gas chambers 332a to 332e of the inner upper electrode 302. The branch flow paths 273a to 273e are respectively provided with opening/closing valves 283a to 283e. The opening/closing valves 283a to 283e serve to perform switching between supply of additive gases from the respective gas sources 252, 254, 256 and 258 and supply stop. The flow rates of additive gases to be supplied to the gas chambers 332a to 332e of the inner upper electrode 302 are controlled by, for example, the flow rate adjustment valves 263, 265, 267 and 269.

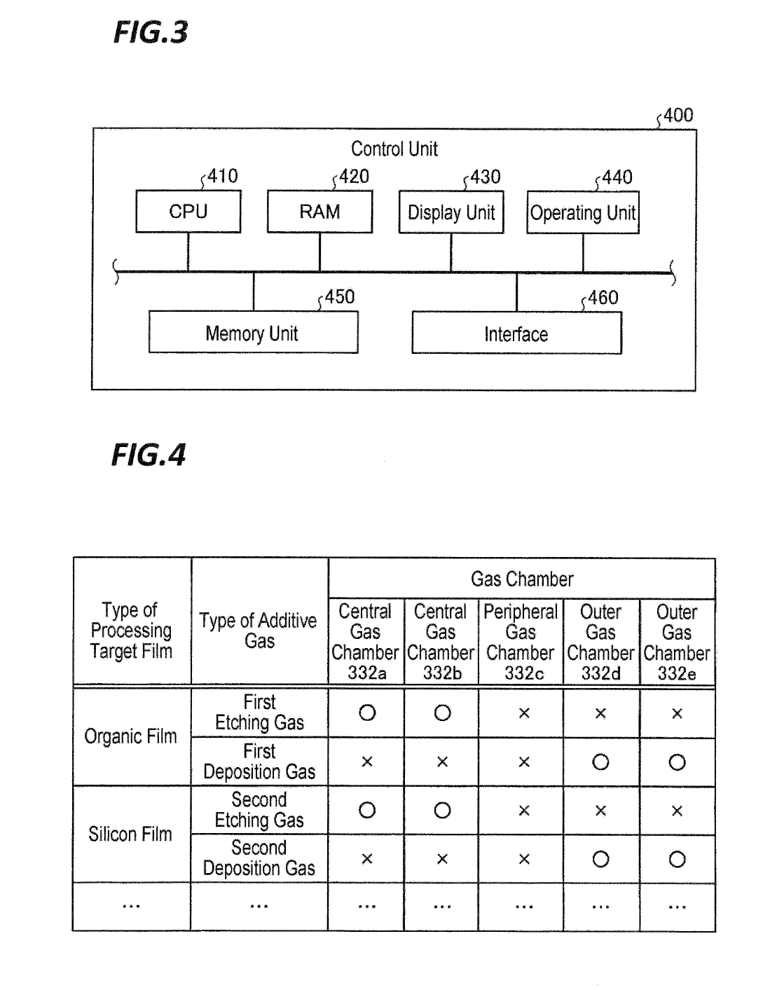

In addition, the respective components of the plasma processing apparatus 100 are connected to and controlled by the control unit 400. FIG. 3 is a block diagram illustrating an exemplary configuration of a control unit in the present exemplary embodiment. As illustrated in FIG. 3, the control unit 400 includes a central processing unit (CPU) 410 that constitutes a main body of the control unit, a random access memory (RAM) 420 provided with, for example, a memory area for use in various data processings executed by the CPU 410, a display unit 430 constituted with, for example, a liquid crystal display that displays, for example, an operating screen or a selection screen, an operating unit 440 constituted with, for example, a touch panel on which perform various data input such as, for example, input or editing of process recipes, and various data output such as, for example, output of a process recipe or process/log output to a prescribed storage medium, may be performed by an operator, a memory unit 450, and an interface 460.

The memory unit 450 stores, for example, a processing program to execute various processings of the plasma processing apparatus 100 and information (data) required for execution of the processing program. The memory unit 450 includes, for example, a memory and a hard disk drive (HDD). An exemplary structure of data stored in the memory unit 450 will be described later.

The CPU 410 reads, for example, program data to execute various processing programs as needed.

The interface 460 is connected to respective components of the processing gas supply unit 200 and the additive gas supply unit 250 which perform control by the CPU 410. The interface 460 includes, for example, a plurality of I/O ports.

The CPU 410, the RAM 420, the display unit 430, the operating unit 440, the memory unit 450, and the interface 460 are connected to one another via bus lines such as, for example, a control bus and a data bus.

For example, the control unit 400 controls the respective components of the plasma processing apparatus 100 to execute a gas supply method that will be described hereinafter. In a detailed example, the control unit 400 selects a combination of gas chambers to be supplied with additive gases, among the gas chambers 332a to 332e of the inner upper electrode 302, and the types of additive gas according to the type of processing target film formed on a substrate, and supplies the additive gases from the additive gas supply unit 250 to the gas chambers 332a to 332e, based on the selected combination. Here, the substrate refers to, for example, a wafer W. In addition, the processing target film corresponds to, for example, an organic film or a silicon film. In addition, the control unit 400 executes a gas supply method using data stored in the memory unit 450.

Here, an exemplary structure of data stored in the memory unit 450 will be described. FIG. 4 is a view illustrating an exemplary structure of data stored in the memory unit in the present exemplary embodiment. As illustrated in FIG. 4, the memory unit 450 stores combinations of the types of additive gas and gas chambers in association with the types of processing target film. The types of processing target film refer to the types of processing target film formed on wafers W which become objects to be subjected to a plasma process. The types of additive gas refer to the types of gas supplied into any of the gas chambers 332a to 332e of the inner upper electrode 302 according to the types of processing target film. The gas chambers refer to gas chambers supplied with additive gases in practice, among the gas chambers 332a to 332e of the inner upper electrode 302. The symbol “0” indicates a gas chamber to be supplied with an additive gas in practice, and the symbol “x” indicates a gas chamber not to be supplied with an additive gas.

For example, the first line of FIG. 4 in which “Organic Film” is written indicates that, in the case where the processing target film on the wafer W is an organic film, a combination of supplying the first etching gas to the central gas chambers 332a and 332b among the gas chambers 332a to 332e of the inner upper electrode 302 may be selected. In addition, for example, the first line of the FIG. 4 indicates that, in the case where the processing target film on the wafer W is an organic film, a combination of supplying the first deposition gas into the outer gas chambers 332d and 332e among the gas chambers 332a to 332e of the inner upper electrode may be selected. In addition, for example, the second line of FIG. 4 in which “Silicon Film” is written indicates that, in the case where the processing target film on the wafer W is a silicon film, a combination of supplying the second etching gas to the central gas chambers 332a and 332b among the gas chambers 332a to 332e of the inner upper electrode 302 may be selected. In addition, for example, the second line of FIG. 4 indicates that, in the case where the processing target film on the wafer W is a silicon film, a combination of supplying the second deposition gas to the outer gas chambers 332d and 332e among the gas chambers 332a to 332e of the inner upper electrode 302 may be selected.

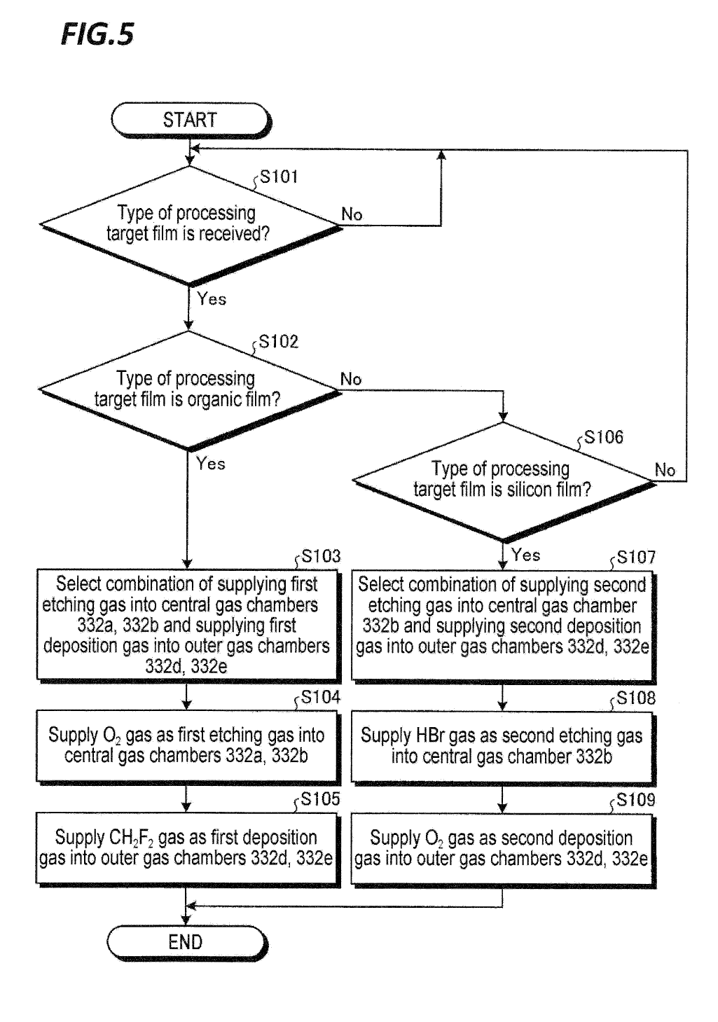

Next, descriptions will be made on a gas supply method using the plasma processing apparatus 100 illustrated in FIG. 1. FIG. 5 is a flowchart illustrating a processing sequence of the gas supply method by the plasma processing apparatus according to the present exemplary embodiment. The gas supply method illustrated in FIG. 5, for example, is executed after supplying a processing gas from the processing gas supply unit 200 into the processing chamber 110 and before executing a plasma processing to turn the processing gas injected into the processing chamber 110 into plasma. In addition, the example illustrated in FIG. 5 illustrates a case in which a wafer W formed with an organic film or a silicon film as a processing target film is placed in the processing chamber 110.

As illustrated in FIG. 5, the control unit 400 of the plasma processing apparatus 100 determines whether a type of processing target film is received (step S101). For example, the control unit 400 receives the type of processing target film from the operating unit 440. In addition, the control unit 400 may receive the type of processing target film as a detection result from a detection unit, such as, for example, a detection sensor that autonomously detects the type of processing target film. In addition, the control unit 400 may keep a table, in which a time for changing the types of processing target film and the type of the processing target film after changing are associated with each other, in the memory unit 450, and when the time for changing the types of processing target film arrives, the control unit 400 may receive the type of processing target film corresponding to the time from the table. When the type of processing target film is not received (step S101; No), the control unit 400 waits.

Meanwhile, when the type of processing target film is received (step S101; Yes), the control unit 400 determines whether the received type of processing target film indicates an organic film (step S102). When the type of processing target film is an organic film (step S102; Yes), the control unit 400 selects, with reference to the memory unit 450, the combination of supplying the first etching gas into the central gas chambers 332a and 332b and supplying the first deposition gas into the outer gas chambers 332d and 332e (step S103). For example, the control unit 400 selects, from the memory unit 450, a combination of supplying O₂ gas as the first etching gas to the central gas chamber 332a and supplying CH₂F₂ gas as the first deposition gas to the outer gas chamber 332d, as a combination corresponding to the organic film.

Subsequently, the control unit 400 supplies O₂ gas as the first etching gas to the central gas chambers 332a and 332b based on the selected combination (Step S104). For example, the control unit 400 controls the flow rate adjustment valve 262 of the additive gas supply unit 250 and the opening/closing valves 282a and 282b to be switched to the open state, thereby supplying O₂ gas as the first etching gas to the central gas chambers 332a and 332b. The O₂ gas as the first etching gas supplied into the central gas chambers 332a and 332b is ejected, along with the processing gas, from the gas ejection holes 312 to the central portion of the wafer W.

Subsequently, the control unit 400 supplies CH₂F₂ gas as the first deposition gas to the outer gas chambers 332d and 332e based on the selected combination (Step S105). For example, the control unit 400 controls the flow rate adjustment valve 265 of the additive gas supply unit 250 and the opening/closing valves 283d and 283e to be switched to the open state, thereby supplying CH₂F₂ gas as the first deposition gas to the outer gas chambers 332d and 332e. The CH₂F₂ gas as the first deposition gas supplied into the outer gas chambers 332d and 332e is ejected, along with the processing gas, from the gas ejection holes 312 to a position outside of the peripheral portion of the wafer W.

Meanwhile, when the received type of processing target film is not the organic film (NO in Step S102), the control unit 400 determines whether the received type of the processing target film is a silicon film (Step S106). When the type of processing target film is not the silicon film (step S106; No), the control unit 400 returns the process to step S101. When the received type of the processing target film is the silicon film (in step S106; Yes), the control unit 400 selects, with reference to the memory unit 450, the combination of supplying the second etching gas into the central gas chamber 332b and supplying the second deposition gas into the outer gas chambers 332d and 332e (step S107). For example, the control unit 400 selects, from the memory unit 450, a combination to supplying HBr gas as the second etching gas to the central gas chamber 332b and supplying O₂ gas as the second deposition gas to the outer gas chamber 332d, as a combination corresponding to the silicon film.

Subsequently, the control unit 400 supplies HBr gas as the second etching gas to the central gas chamber 332b based on the selected combination (step S108). For example, the control unit 400 controls the flow rate adjustment valve 266 of the additive gas supply unit 250 and the opening/closing valve 282b to be to the open state, thereby supplying HBr gas as the second etching gas to the central gas chamber 332b. The HBr gas as the second etching gas supplied to the central gas chambers 332b is ejected, along with the processing gas, from the gas ejection holes 312 to the central portion of the wafer W.

Subsequently, the control unit 400 supplies O₂ gas as the second deposition gas to the outer gas chambers 332d and 332e based on the selected combination (step S109). For example, the control unit 400 controls the flow rate adjustment valve 269 of the additive gas supply unit 250 and the opening/closing valves 283d and 283e to be switched to the open state, thereby supplying O₂ gas as the second deposition gas to the outer gas chambers 332d and 332e. The O₂ gas as the second deposition gas supplied to the outer gas chambers 332d and 332e is ejected, along with the processing gas, from the gas ejection holes 312 to a position outside of the peripheral portion of the wafer W.

Thereafter, a plasma processing is performed so as to turn the processing gas and the additive gases supplied into the processing chamber 110 into plasma. When the plasma processing is performed, active species such as, for example, ions, are generated from the gas turned into plasma and the processing target film on the wafer W is etched by the active species.

As described above, in the present exemplary embodiment, a combination of gas chambers to be supplied with additive gases among the gas chambers 332a to 332e and the types of additive gas is selected according to the type of processing target film formed on the substrate and, based on the selected combination, the additive gases are supplied into the gas chambers 332a to 332e. For this reason, even when the types of processing target film are changed, the supply positions of the additive gases and the types of additive gas may be appropriately changed depending on the type of processing target film after the types of processing target film are changed. In other words, among the gas chambers 332a to 332e, the type of additive gas injected from the central gas chambers 332a and 332b to an area near the central portion of a wafer W and the type of additive gas injected from the outer gas chambers 332d and 332e to an area near the peripheral portion of the wafer W may be changed depending on the type of the processing target film. As a result, even when the types of processing target film are changed, an etch rate near the central portion of the wafer W and an etch rate near the peripheral portion of the wafer W may be relatively adjusted. Thus, the uniformity of processing target surfaces of processing target films may be appropriately maintained according to the change of the processing target films.

In addition, in the present exemplary embodiment, since the first deposition gas or the second deposition gas is supplied to the outer gas chambers 332d and 332e among the gas chambers 332a to 332e, the deposition gas injected to an area near the peripheral portion of the wafer W may be suppressed from entering the area near the central portion of the wafer W. Thus, the etch rate near the central portion of the wafer W may be suppressed from being inadvertently changed due to the deposition gas. As a result, the uniformity of the processing target surface of a processing target film may be maintained with high accuracy.

In addition, the processing sequence is not limited to the sequence described above and may be appropriately changed so long as this change does not conflict with the processing contents. For example, step S104 and step S105 may be executed concurrently. In addition, for example, step S108 and step S109 may be executed concurrently.

Although FIG. 5 illustrates an example of selecting a combination of supplying the first etching gas to the central gas chambers and supplying the first deposition gas to the outer gas chambers when the received type of processing target film is an organic film, selectable combinations are not limited thereto. For example, in step S103, a combination of supplying the first etching gas to the central gas chambers may be selected. When the combination of supply the first etching gas to the central gas chambers is selected in step S103, the step S105 described above may be omitted. In addition, for example, in step S103, a combination of supplying the first deposition gas to the outer gas chambers may be selected. When the combination of supplying the first deposition gas to the outer gas chambers is selected in step S103, the step S104 described above may be omitted.

In addition, although FIG. 5 illustrates an example of selecting a combination of supplying the second etching gas to the central gas chamber and supplying the second deposition gas to the outer gas chamber when the received type of processing target film is a silicon film, selectable combinations are not limited thereto. For example, in step S107, a combination of supplying the second etching gas into the central gas chamber may be selected. When the combination of supplying the second etching gas into the central gas chambers is selected in step S107, the step S109 described above may be omitted. In addition, for example, in step S107, a combination of supplying the second deposition gas to the outer gas chambers may be selected. When the combination of supply the second deposition gas to the outer gas chambers is selected in step S107, the step S108 described above may be omitted.

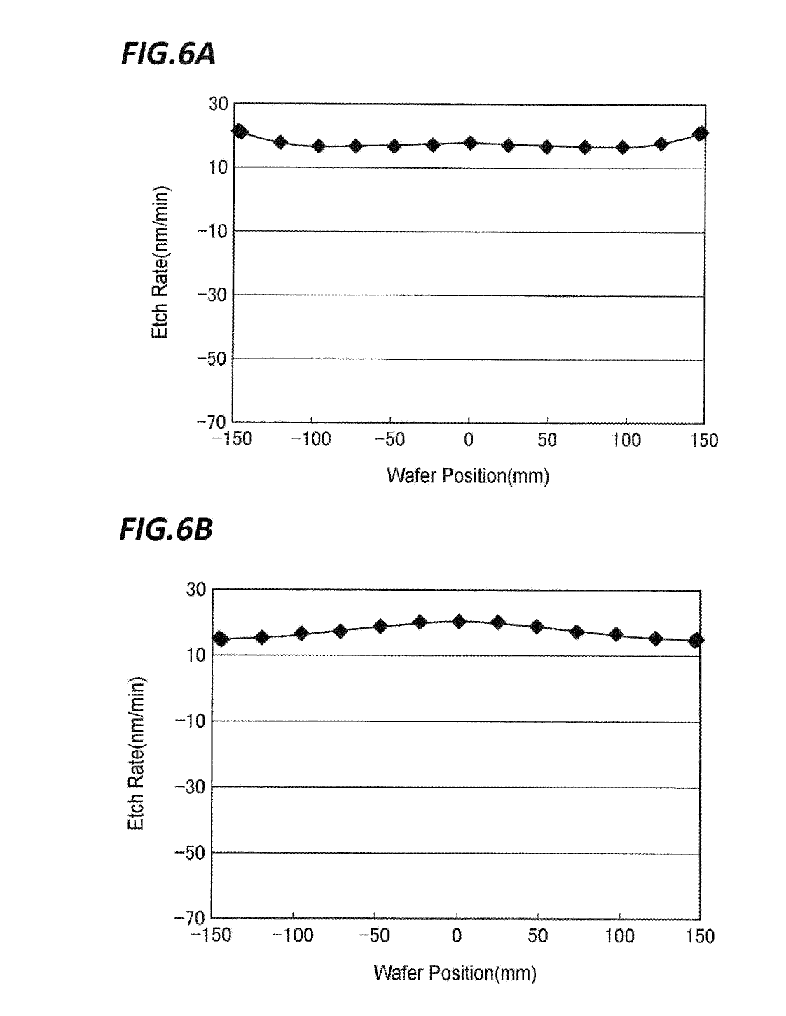

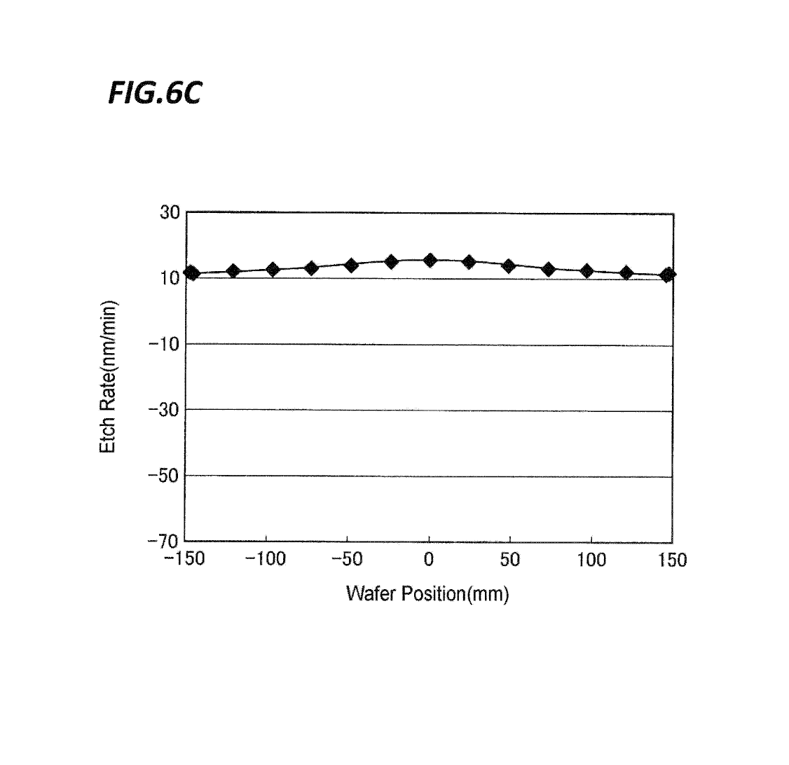

Next, descriptions will be made on effects obtained by the gas supply method and the plasma processing apparatus of the present exemplary embodiment. FIG. 6A is a view illustrating an etch rate when a wafer was etched without using the gas supply method of the present exemplary embodiment. FIGS. 6B and 6C are views each illustrating an etch rate when a wafer was etched using the gas supply method of the present exemplary embodiment.

In FIG. 6A, the vertical axis represents an etch rate (nm/min) when a BARC as an organic film on a wafer W was etched using a processing gas of CF₄/CHF₃/O₂=100 sccm/100 sccm/3 sccm. In FIG. 6B, the vertical axis representing an etch rate (nm/min) when first deposition gas of CH₂F₂=10 sccm was supplied into the outer gas chambers 332d and a BARC as an organic film on a wafer W was etched using a processing gas of CF₄/CHF₃/O₂=100 sccm/100 sccm/3 sccm. In FIG. 6C, the vertical axis represents an etch rate (nm/min) when the first deposition gas of CH₂F₂=10 sccm was supplied into the outer gas chamber 332e and a BARC as an organic film on a wafer W was etched using a processing gas of CF₄/CHF₃/O₂=100 sccm/100 sccm/3 sccm. In addition, in FIGS. 6A to 6C, each horizontal axis represents a radial position in of a wafer W. That is, FIGS. 6A to 6C illustrate that an etch rate from a position of “−150 (mm)” to a position of “+150 (mm)” position of a wafer W, assuming that the position of center of the wafer W is “0”. In FIGS. 6A to 6C, the pressure of 60 mTorr (8 Pa) within the processing chamber 110 and output of the first high frequency power source/output of the second high frequency power source=300 W/50 W were used as other conditions.

As illustrated in FIG. 6A, when the gas supply method of the present exemplary embodiment was not used, the etch rate at the peripheral portion of the wafer W increased compared to the etch rate at the central portion of the wafer W. That is, when CH₂F₂ as first deposition gas was not supplied into the outer gas chambers 332d and 332e, the difference between the etch rate at the central portion of the wafer W and the etch rate at the peripheral portion of the wafer W did not satisfy a predetermined allowable specification.

Whereas, as illustrated in FIGS. 6B and 6C, when the gas supply method of the present exemplary embodiment was used, the etch rate at the peripheral portion of each wafer W and the etch rate at the central portion of each wafer W were adjusted to be relatively uniform. That is, when CH₂F₂ as first deposition gas was supplied to the outer gas chambers 332d and 332e, the difference between the etch rate at the central portion of each wafer W and the etch rate at the peripheral portion of each wafer W satisfied a predetermined allowable specification.

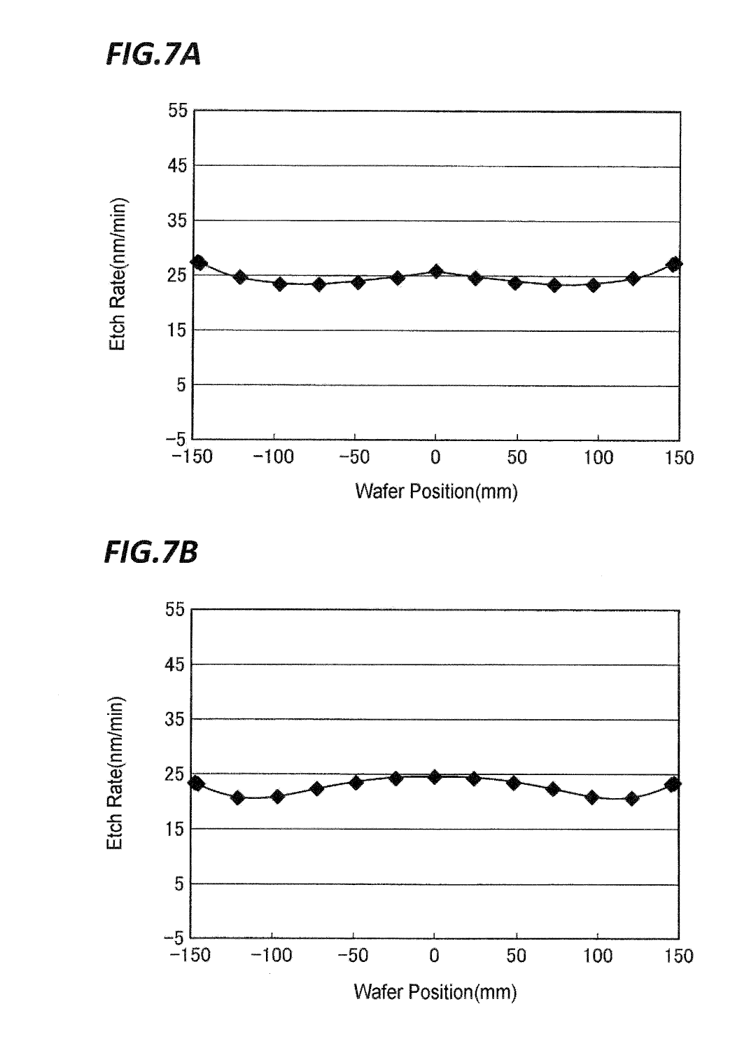

FIG. 7A is a view illustrating an etch rate when a wafer was etched without using the gas supply method of the present exemplary embodiment. FIG. 7B is a view illustrating an etch rate when a wafer was etched using the gas supply method of the present exemplary embodiment.

In FIG. 7A, the vertical axis represents an etch rate (nm/min) when a BARC as an organic film on the wafer W was etched using a processing gas of CF₄/CHF₃=100 sccm/100 sccm. In addition, in FIG. 7B, the vertical axis designates an etch rate (nm/min) when the first etching gas of O₂=3 sccm was supplied to the central gas chamber 332b and a BARC as an organic film on the wafer W was etched using a processing gas of CF₄/CHF₃=100 sccm/100 sccm. In addition, in FIGS. 7A and 7B, the horizontal axis represents a radial position of a wafer W. That is, FIGS. 7A and 7B illustrate that the etch rate from a position of “−150 (mm)” to a position of “+150 (mm)” of a wafer W, assuming that the position of center of the wafer W is “0”. In addition in FIGS. 7A and 7B, the pressure of 60 mTorr (8 Pa) within the processing chamber 110 and output of the first high frequency power source/output of the second high frequency power source=300 W/50 W were used as other conditions.

As illustrated in FIG. 7A, when the gas supply method of the present exemplary embodiment was not used, the etch rate at the peripheral portion of the wafer W increased compared to the etch rate at the central portion of the wafer W. That is, when O₂ as first etching gas was not supplied into the central gas chamber 332b, the difference between the etch rate at the central portion of the wafer W and the etch rate at the peripheral portion of the wafer W did not satisfy a predetermined allowable specification.

Whereas, as illustrated in FIG. 7B, when the gas supply method of the present exemplary embodiment was used, the etch rate at the peripheral portion of the wafer W and the etch rate at the central portion of the wafer W were adjusted to be relatively uniform. That is, when O₂ as first etching gas was supplied to the central gas chamber 332b, the difference between the etch rate at the central portion of the wafer W and the etch rate at the peripheral portion of the wafer W satisfied a predetermined allowable specification.

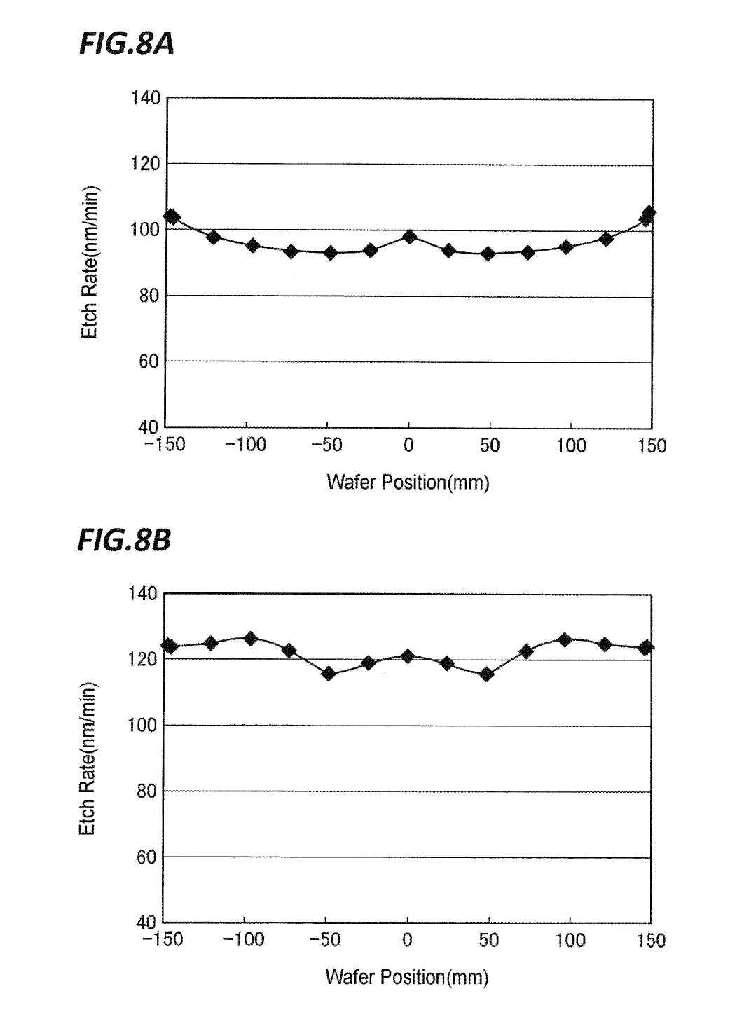

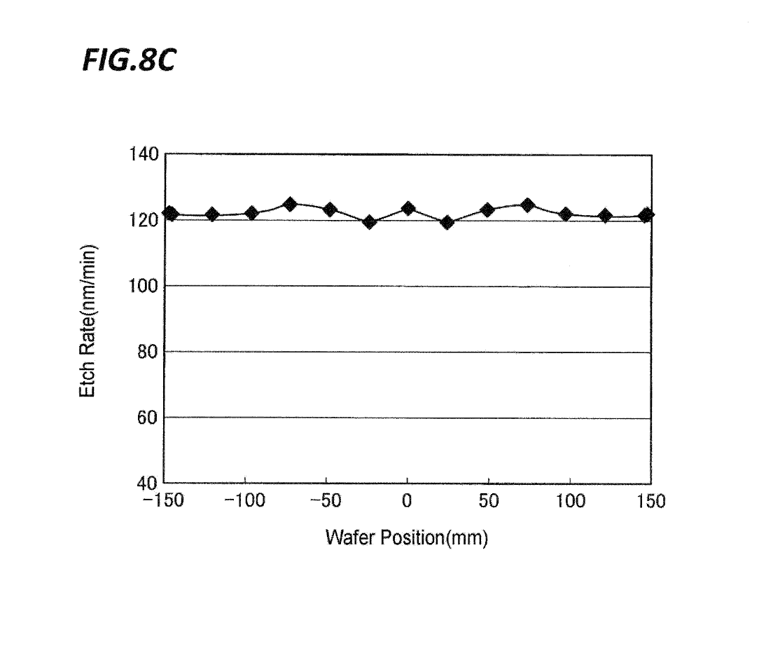

FIG. 8A is a view illustrating an etch rate when a wafer was etched without using the gas supply method of the present exemplary embodiment. FIGS. 8B and 8C are views each illustrating an etch rate when a wafer was etched using the gas supply method of the present exemplary embodiment.

In FIG. 8A, the vertical axis represents an etch rate (nm/min) when a silicon film on a wafer W was etched using processing gas of O₂=6 sccm. In addition, in FIG. 8B, the vertical axis illustrates an etch rate (nm/min) when the second etching gas of HBr=360 sccm was supplied to the central gas chamber 332a and a silicon film on a wafer W was etched using processing gas of O₂=6 sccm. In addition, in FIG. 8C, the vertical axis an etch rate (nm/min) when the second etching gas of HBr=360 sccm was supplied to the central gas chamber 332b and a silicon film on a wafer W was etched using a processing gas of O₂=6 sccm. In addition, in FIGS. 8A to 8C, the horizontal axis represents a radial position of a wafer W. That is, FIGS. 8A to 8C illustrate that the etch rate from a position of “−150 (mm)” to a position of “+150 (mm)” of a wafer W, assuming that the position of center of the wafer W is “0”. In addition in FIGS. 8A to 8C, the pressure of 10 mTorr (1.3 Pa) within the processing chamber 110 and output of the first high frequency power source/output of the second high frequency power source=200 W/200 W were used as other conditions.

As illustrated in FIG. 8A, when the gas supply method of the present exemplary embodiment was not used, the etch rate at the central portion of the wafer W decreased compared to the etch rate at the peripheral portion of the wafer W. That is, when HBr gas as the second etching gas was not supplied to the central gas chambers 332a and 332b, the difference between the etch rate at the central portion of the wafer W and the etch rate at the peripheral portion of the wafer W did not satisfy a predetermined allowable specification.

On the other hand, as illustrated in FIGS. 8B and 8C, when the gas supply method of the present exemplary embodiment was used, the etch rate at the peripheral portion of each wafer W and the etch rate at the central portion of each wafer W were adjusted to be relatively uniform. That is, when HBr as the second etching gas was supplied to the central gas chambers 332a and 332b, the difference between the etch rate at the central portion of each wafer W and the etch rate at the peripheral portion of each wafer W satisfied a predetermined allowable specification.

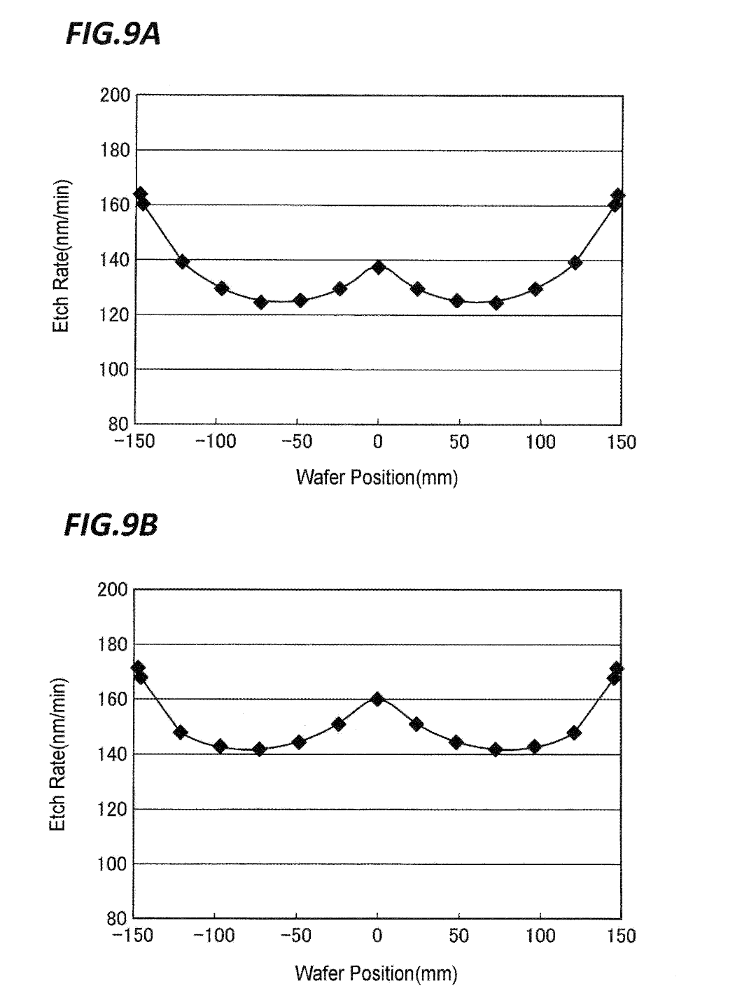

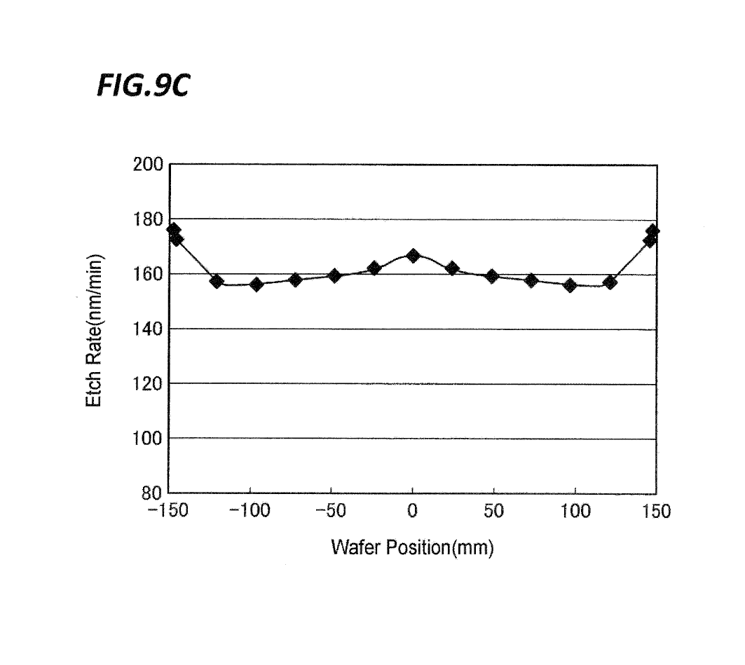

FIG. 9A is a view illustrating an etch rate when a wafer was etched without using the gas supply method of the present exemplary embodiment. FIGS. 9B and 9C are views each illustrating an etch rate when a wafer was etched using the gas supply method of the present exemplary embodiment.

In FIG. 9A, the vertical axis represents an etch rate (nm/min) when a silicon film on a wafer W was etched using a processing gas of HBr/He/O₂=180 sccm/100 sccm/7 sccm. In addition, in FIG. 9B, the vertical axis represents an etch rate (nm/min) when the second etching gas of NF₃=37 sccm was supplied into the central gas chamber 332a and a silicon film on the wafer W was etched using a processing gas of HBr/He/O₂=180 sccm/100 sccm/7 sccm. In addition, in FIG. 9C, the vertical axis represents an etch rate (nm/min) when the second etching gas of NF₃=37 sccm was supplied into the central gas chamber 332b and a silicon film on a wafer W was etched using a processing gas of HBr/He/O₂=180 sccm/100 sccm/7 sccm. In addition, in FIGS. 9A to 9C, the horizontal axis represents a radial position of a wafer W. That is, FIGS. 9A to 9C illustrate that the etch rate from a position of “−150 (mm)” to a position of “+150 (mm)” of a wafer W, assuming that the position of center of the wafer W is “0”. In addition in FIGS. 9A to 9C, the pressure of 15 mTorr (2 Pa) within the processing chamber 110 and output of the first high frequency power source/output of the second high frequency power source=300 W/270 W were used as other conditions.

As illustrated in FIG. 9A, when the gas supply method of the present exemplary embodiment was not used, the etch rate at the central portion of the wafer W decreased compared to the etch rate at the central portion of the wafer W. That is, when NF₃ as second etching gas was not supplied to the central gas chambers 332a and 332b, the difference between the etch rate at the central portion of the wafer W and the etch rate at the peripheral portion of the wafer W did not satisfy a predetermined allowable specification.

Whereas, as illustrated in FIGS. 9B and 9C, when the gas supply method of the present exemplary embodiment was used, the etch rate at the peripheral portion of each wafer W and the etch rate at the central portion of each wafer W were adjusted to be relatively uniform. That is, when NF₃ as second etching gas was supplied to the central gas chambers 332a and 332b, the difference between the etch rate at the central portion of each wafer W and the etch rate at the peripheral portion of each wafer W satisfied a predetermined allowable specification.

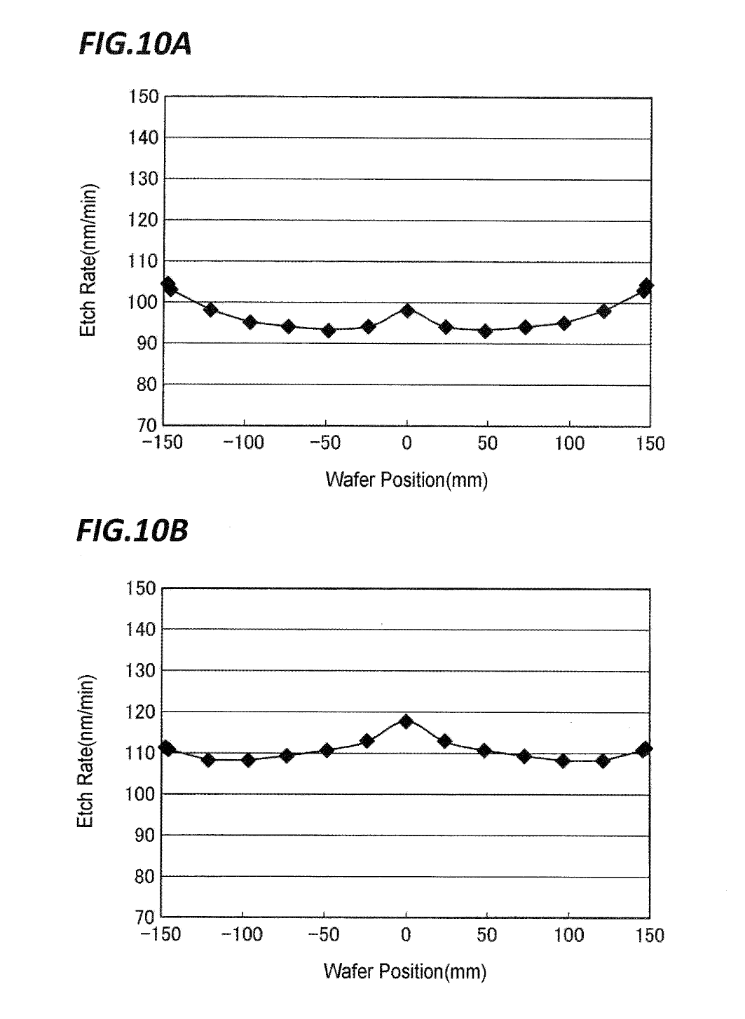

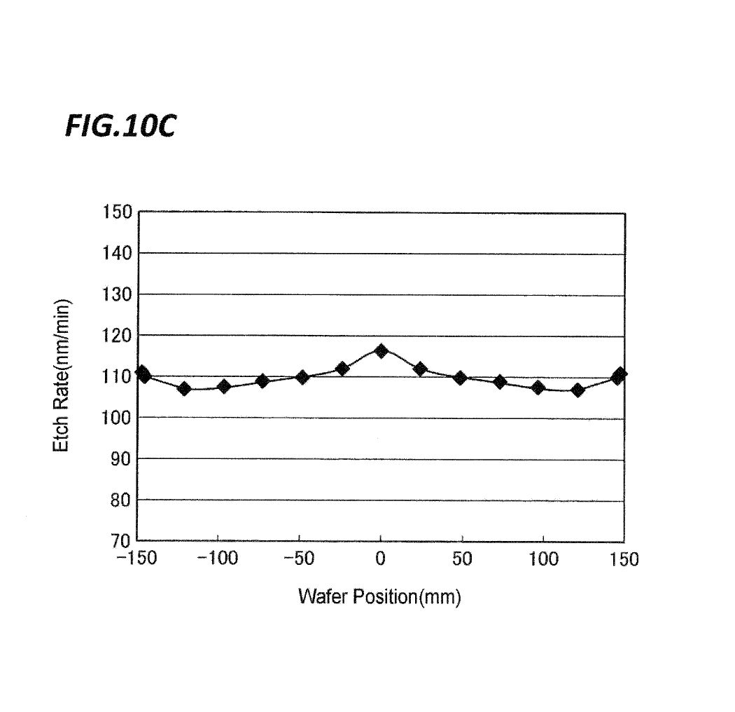

FIG. 10A is a view illustrating an etch rate when a wafer was etched without using the gas supply method of the present exemplary embodiment. FIGS. 10B and 10C are views each illustrating an etch rate when a wafer was etched using the gas supply method of the present exemplary embodiment.

In FIG. 10A, the vertical axis represents an etch rate (nm/min) when a silicon film on a wafer W was etched using a processing gas of HBr=360 sccm. In addition, in FIG. 10B, the vertical axis represents an etch rate (nm/min) when the second deposition gas of O₂=6 sccm was supplied to the outer gas chamber 332d and a silicon film on a wafer W was etched using a processing gas of HBr=360 sccm. In addition, in FIG. 10C, the vertical axis represents an etch rate (nm/min) when the second deposition gas of O₂=6 sccm was supplied to the outer gas chamber 3323e and a silicon film on a wafer W was etched using a processing gas of HBr=360 sccm. In addition, in FIGS. 10A to 10C, the horizontal axis represents a radial position on a wafer W. That is, FIGS. 10A to 10C illustrate that the etch rate from a position of “−150 (mm)” to a position of “+150 (mm)” of a wafer W, assuming that the position of center of the wafer W is “0”. In addition in FIGS. 10A to 10C, the pressure of 10 mTorr (1.3 Pa) within the processing chamber 110 and output of the first high frequency power source/output of the second high frequency power source=200 W/200 W were used as other conditions.

As illustrated in FIG. 10A, when the gas supply method of the present exemplary embodiment was not used, the etch rate at the central portion of the wafer W decreased compared to the etch rate at the central portion of the wafer W. That is, when O₂ as second deposition gas was not supplied to the outer gas chambers 332d and 332e, the difference between the etch rate at the central portion of the wafer W and the etch rate at the peripheral portion of the wafer W did not satisfy a predetermined allowable specification.

Whereas, as illustrated in FIGS. 9B and 9C, when the gas supply method of the present exemplary embodiment was used, the etch rate at the peripheral portion of each wafer W and the etch rate at the central portion of each wafer W were adjusted to be relatively uniform. That is, when O₂ as second deposition gas was supplied into the outer gas chambers 332d and 332e, the difference between the etch rate at the central portion of each wafer W and the etch rate at the peripheral portion of each wafer W satisfies a predetermined allowable specification.

### DESCRIPTION OF SYMBOL

100: plasma processing apparatus
110: processing chamber
250: additive gas supply unit
252, 254, 256, 258: gas source
262, 264, 266, 268: flow rate adjustment valve
282a to 282e: opening/closing valve
300: upper electrode
302: inner upper electrode (gas injection unit)
332a to 332e: gas chamber
400: control unit

1. A gas supply method comprising:
a selection step of selecting a combination of a gas chamber to be supplied with an additive gas among a plurality of gas chambers divided from a gas injection unit by partitions and a type of additive gas according to a type of processing target film, the gas injection unit being configured to inject a processing gas for use in a plasma processing into a processing chamber in which a substrate formed with the processing target film is placed; and
an additive gas supply step of supplying the additive gas into the gas chamber based on the combination selected by the selection step.

2. The gas supply method according to claim 1, wherein the selection step selects the combination of supplying a first etching gas as the additive gas to the gas chamber located at a position corresponding to a central portion of the substrate, among the gas chambers when the type of processing target film is an organic film.

3. The gas supply method according to claim 1, wherein the selection step selects the combination of supplying a first deposition gas as the additive gas to the gas chamber located at a position outside of a peripheral portion of the substrate, among the gas chambers when the type of processing target film is an organic film.

4. The gas supply method according to claim 1, wherein the selection step selects the combination of supplying a second etching gas as the additive gas to the gas chamber located at a position corresponding to a central portion of the substrate, among the gas chambers when the type of processing target film is a silicon film.

5. The gas supply method according to claim 1, wherein the selection step selects the combination of supplying a second deposition gas as the additive gas to the gas chamber located at a position outside of a peripheral portion of the substrate, among the gas chambers when the type of processing target film is a silicon film.

6. The gas supply method according to claim 2, wherein the first etching gas is O₂ gas.

7. The gas supply method according to claim 3, wherein the first deposition gas is at least one of a CF-based gas and COS gas.

8. The gas supply method according to claim 4, wherein the second etching gas is at least one of HBr gas, NF₃ gas, and Cl₂ gas.

9. The gas supply method according to claim 5, wherein the second deposition gas is O₂ gas.

10. A plasma processing apparatus comprising:
a processing chamber in which a substrate formed with a processing target film is placed;
a gas injection unit configured to inject a processing gas for use in plasma processing into the processing chamber;
an additive gas supply unit configured to supply an additive gas to a plurality of gas chambers obtained by partitioning the gas injection unit; and
a control unit configured to select a combination of a gas chamber to be supplied with the additive gas among the gas chambers and a type of additive gas according to a type of processing target film, and to supply the additive gas from the additive gas supply unit to the gas chamber based on the selected combination.
